(19) United States
(12) Patent Application Publication
(10) Pub. No.: US 2015/0378055 A1
(43) Pub. Date: Dec. 31, 2015

(54) OPTICAL ELEMENT WITH SAPPHIRE CRYSTALLOGRAPHIC STRUCTURE HAVING PLURALITY OF CRYSTAL PLANES

(71) Applicant: Vertu Corporation Limited, Hampshire (GB)

(72) Inventors: Stuart GODFREY, Hook (GB); Stewart DEWEY, Middlesex (GB)

(21) Appl. No.: 14/845,711

(22) Filed: Sep. 4, 2015

Related U.S. Application Data
(63) Continuation of application No. PCT/EP2013/054562, filed on Mar. 7, 2013.

(51) Int. Cl. G02B 1/02; C30B 29/20; C30B 33/00; G02B 1/14

(52) U.S. Cl. CPC G02B 1/02; G02B 1/14; C30B 29/20; C30B 33/00

(57) ABSTRACT

An optical element, having a length in a direction of a first axis and a width in a direction of a second axis, wherein the length is greater than or equal to the width. The optical element includes a sapphire crystallographic structure having a plurality of crystal planes, wherein a first crystal plane axis is configured to be perpendicular to the first and the second axis, a second crystal plane axis is configured to be parallel to the first axis and a third crystal plane axis is configured to be parallel to the second axis.

### CROSS REFERENCE TO RELATED APPLICATIONS

This application is a continuation of PCT International Patent Application No. PCT/EP2013/054562 filed Mar. 7, 2013, the entire disclosure of which is incorporated herein by reference.

### TECHNICAL FIELD

The present invention relates generally to optical elements. The invention relates particularly, though not exclusively, to using sapphire crystallographic structure having a plurality of crystal planes in the optical element of an apparatus.

### BACKGROUND ART

Portable apparatuses, such as mobile phones, tablets and personal computers all need optical elements, such as transparent plastics and glass when constructing the product. With increasing consumer awareness of quality and value mobile manufacturers are continuing to use more and more quality materials. With respect to mobile phones and tablets, the last couple of years have seen a market shift from use of plastic screens to more scratch resistant chemical toughened glass (for example Gorilla® Glass).

While Gorilla® Glass is a significant improvement over plastic it can still be scratched by everyday items such as keys or coins in bags and pockets. Also, the glass is easily fractured if the product is dropped. For this reason sapphire, for example, is being considered more and more for use on consumer goods. Sapphire is the second hardest naturally occurring material and can only be scratched by diamonds. Sapphire is also a strong material and has a very high elastic modulus (stiffness). Thus, using sapphire in the construction of mobile apparatuses creates a very stiff product that is less likely to flex during accidental drop or impact. This makes sapphire a very resistant, long lasting material for mobile apparatus usage.

However, sapphire is more expensive and heavier material than plastic or Gorilla® Glass and at the same time sizes of optical elements, such as display screens, tend to increase. Thus, especially for portable apparatuses an improved solution is needed to provide an optical element made of sapphire that is thinner than known solutions but still meets the strict requirements for portable apparatuses regarding to maximum strength and robustness.

### SUMMARY

According to a first example aspect of the invention there is provided an optical element, the element having a length in a direction of a first axis and a width in a direction of a second axis, wherein the length is greater than or equal to the width, the optical element further comprising:
a sapphire crystallographic structure having a plurality of crystal planes, wherein a first crystal plane axis is configured to be perpendicular to the first and the second axis, a second crystal plane axis is configured to be parallel to the first axis and a third crystal plane axis is configured to be parallel to the second axis.

In an embodiment, a sapphire crystallographic structure having a plurality of crystal planes, wherein three major planes maybe be represented by three orthogonal axis, wherein a first crystal plane axis is configured to be perpendicular to the second crystal plane axis and the third crystal plane axis is configured to be perpendicular to the first crystal plane axis and the second crystal plane axis.

In an embodiment, the plurality of crystal planes comprises:
A-plane with A-axis configured to be a normal axis of the A-plane;
C-plane with C-axis configured to be a normal axis of the C-plane, the C-axis being perpendicular to the A-axis; and
M-plane with M-axis configured to be a normal axis of the M-plane, the M-axis being perpendicular to the A-axis and the C-axis.

In an embodiment, the plurality of crystal planes comprises:
A-plane with A-axis configured to be a normal axis of the A-plane, the A-axis being perpendicular to the C-axis and perpendicular to the M-axis; and
C-plane with C-axis configured to be a normal axis of the C-plane, the C-axis being perpendicular to the A-axis and perpendicular to the M-axis; and
M-plane with M-axis configured to be a normal axis of the M-plane, the M-axis being perpendicular to the A-axis and perpendicular to the C-axis.

In an embodiment, the first crystal plane axis is the A-axis, the second crystal plane axis is the M-axis and the third crystal plane axis is the C-axis.

In an embodiment, a fourth crystal plane axis is configured to be perpendicular to the first crystal plane axis and inclined to the second and the third crystal plane axes.

In an embodiment, the plurality of crystal planes comprises:
R-plane with R-axis configured to be a normal axis of the R-plane.

In an embodiment, the optical element comprises at least one of the following:
a display glass of an apparatus; and
a cover part of an apparatus.

In an embodiment, the optical element has a length in a direction of the M-axis and a width in a direction of the C-axis, wherein the length is greater than or equal to the width.

In an embodiment, the optical element is transparent.

According to a second example aspect of the invention there is provided a method for providing an optical element, the method comprising:
obtaining a sapphire crystal of sufficient size for the optical element, the optical element having a length in a direction of a first axis and a width in a direction of a second axis, wherein the length is greater than or equal to the width;
determining a sapphire crystallographic structure having a plurality of crystal planes;
defining a first crystal plane axis to be perpendicular to the first and the second axis, a second crystal plane axis to be parallel to the first axis and a third crystal plane axis to be parallel to the second axis; and
machining the sapphire crystal using the defined crystal plane axes to provide the optical element.

In an embodiment, the method further comprises:
defining the plurality of crystal planes as A-plane with A-axis configured to be a normal axis of the A-plane; C-plane with C-axis configured to be a normal axis of the C-plane, the C-axis being perpendicular to the A-axis; and M-plane with M-axis configured to be a normal axis of the M-plane, the M-axis being perpendicular to the A-axis and the C-axis.

In an embodiment, the first crystal plane axis is the A-axis, the second crystal plane axis is the M-axis and the third crystal plane axis is the C-axis.

In an embodiment, the method further comprises:
machining the sapphire crystal using the defined crystal based axes to provide the optical element, wherein the element having a length in a direction of the M-axis and a width in a direction of the C-axis, wherein the length is greater than or equal to the width.

In an embodiment, the method further comprises:
determining a higher stress direction of an apparatus;
determining a higher strength axis of a sapphire for the optical element; and
aligning the higher strength axis with the higher stress direction.

In an embodiment, the method further comprises:
selecting a first sapphire crystal plane to be parallel with a first plane of the optical element based on desired properties for the optical element;
determining a higher stress direction of an apparatus;
determining a higher strength axis of a sapphire for the optical element; and
aligning the higher strength axis of the sapphire with the higher stress direction of the apparatus.

In an embodiment, the higher strength axis is at least one of the following sapphire crystal axes:
A-axis;
C-axis;
M-axis; and
R-axis.

According to a third example aspect of the invention there is provided an apparatus comprising an optical element of the first aspect.

In an embodiment, a higher strength axis of a sapphire element is aligned with a higher stress direction of the apparatus.

The apparatus may comprise a portable apparatus, such as a tablet, a smartphone, a mobile phone, a laptop, a digital camera or a personal digital assistant (PDA), for example.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well.

### BRIEF DESCRIPTION OF THE DRAWINGS

The invention will be described, by way of example only, with reference to the accompanying drawings, in which:

FIG. 1 shows some details of an apparatus in which various embodiments of the invention may be applied;

FIG. 2 shows a schematic view of a sapphire crystallographic structure having a plurality of crystal planes, in which various embodiments of the invention may be applied;

FIG. 3 presents a schematic view of a sapphire crystallographic structure for an optical element, in which various embodiments of the invention may be applied;

FIG. 4 presents a schematic view of an optical element, in which various embodiments of the invention may be applied;

FIG. 5 presents another schematic view of an optical element, in which various embodiments of the invention may be applied;

FIG. 6 shows a flow diagram showing operations, in accordance with an example embodiment of the invention; and

FIG. 7 presents an example block diagram of an apparatus in which various embodiments of the invention may be applied.

### DETAILED DESCRIPTION

In the following description, like numbers denote like elements.

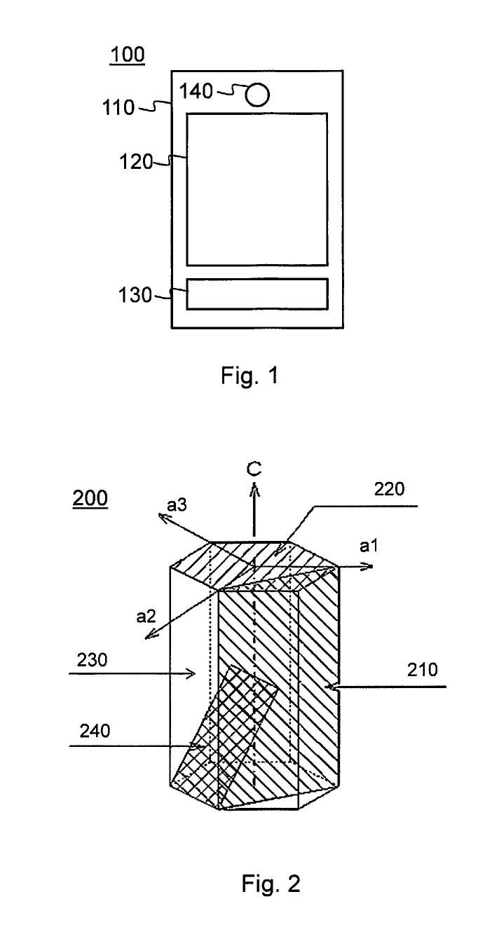

FIG. 1 shows some details of an apparatus 100 in which various embodiments of the invention may be applied.

In an embodiment, the apparatus 100 may comprise a mobile phone, a smart phone, a tablet, a laptop or any other portable apparatus. The apparatus comprises at least one cover part 110 for providing protection to the components of the apparatus 100 and creating desired outlook and outer design for the apparatus 100. The cover part 110 may comprise several separate cover parts, such as front and rear covers and even a side frame. The apparatus 100 further comprises user interface 120, 130 comprising at least one display 120. The display 120 may be a touch-sensitive display for detecting user gestures and providing feedback for the apparatus 100. The apparatus 100 may also comprise a user input device 130, such as a keypad or a touchpad, for example. Furthermore, the apparatus 100 may comprise a camera 140. No matter the described elements 110, 120, 130, 140 are shown on the same side of the apparatus 100, they can be located on any side of the apparatus 100. No matter a plurality of apparatus elements 120-140 are illustrated in FIG. 1, they all need not to be included. For example, only a touch-sensitive display 120 may be included without the need for separate user input device 130.

In an embodiment, at least one of the apparatus elements 110, 120, 130, 140 comprises an optical element, such as transparent sheet, layer or glass, for example. The cover part 110 may comprise an optical element, such as transparent layer coating, to provide good-looking, strong and scratch resistant surface for the apparatus. The display 120 may comprise an optical element, such as a transparent protection layer, to provide strong and scratch-resistant surface for the display but still enable clear visibility for the display 120 from all angles. The user input device may comprise an optical element, similarly as the display, in case of a touchpad, and similarly as the cover part for the keypad frame in case of a traditional keypad. The camera 140 may comprise an optical element, such as protective lens, for example.

In an embodiment, the display 120 may form a permanent part of the cover part 110 or, to increase the potential for upgrading the engine throughout the life of the cover part 110 it may be a module that can be replaced to. Alternatively, a protective layer of the display 120 may be a part of the cover part 110 that layer may be independently exchanged. In further alternative embodiment the protective layer of the display 120 is integrated to the cover part 110.

The cover part 110 may comprise a casing for a portable communication device for receiving an engine for operation of the device, the casing comprising: a surface layer as an optical element, mounted on a defined area of a housing defining, along with the surface layer, an exterior of the housing; and means for engaging the exposed areas of the substrate with the housing. The surface layer can conveniently be adhered to the substrate. The adherent may be a UV curing adhesive, for example.

In embodiments of the invention the surface layer may provide an operating face of the device. This gives a design engineer far greater freedom to design a device with a desirable appearance. The operating face may be provided with a user input element 130, for example a key, or an array of such elements. The casing may be a conventional one part casing or a clam shell, or other two or more part arrangement, where the user input elements 130 or keys may be located on a different face to a display 120.

Sapphire is a single crystal material, i.e. it is grown as a continuous large single crystal without grain boundaries. Such a single crystal may be grown before cutting to a desired size and shape for an optical element.

The sapphire single crystal, i.e., Al₂O₃, is used for usage of wider range, because it has higher hardness and toughness. The single crystal of sapphire may be pulled, growing a seed crystal in contact with the surface of the molten alumina to produce the single crystal into a larger single crystal, so as to generally work the single crystal into the desired shape.

In an embodiment, the sapphire crystal is either cut or grown so that a specific plane within the crystal is parallel to the sheet orientation of the sapphire. Hence sapphire may be referred to as A-plane or C-plane sapphire, for example. Thus for A-plane sapphire the A-plane is parallel to a screen direction of the optical element.

Sapphire single crystal is an anisotropic material. This means that the material has different mechanical properties (strength, hardness, optical properties etc.) depending on the direction of the crystal. In simplest terms, A-plane sapphire is generally the strongest plane whilst C-plane has the best optical properties.

FIG. 2 shows a schematic view of a sapphire crystal structure 200, known also as a unit cell, having a plurality of crystal planes 210-240, in which various embodiments of the invention may be applied.

In the crystal structure of a sapphire, as shown in FIG. 2, the sapphire crystal is a hexagonal system, wherein C-axis forms a central axis being vertical and normal to C-plane 220. Due to the symmetry of the sapphire crystal structure the A-plane has numerous A-axes in FIG. 2, for example axis a1 to a3 that are to be extended in three directions perpendicular to C-axis. Respectively, A-plane 210 is shown in FIG. 2. M-plane 230 is perpendicular to C-plane 220 and A-plane 210. R-plane 240 is oblique at a constant angle to C-axis.

No matter only four planes 210-240 is shown, the crystal cell may comprise other planes. Furthermore, due to crystal symmetry, there may be several identical planes for each major plane. For example, the unit cell 200 may comprise three A-planes 210, three R-planes 240, one C-plane 20 and three M-planes 230, for example.

The C-axis is typically angled approximately 57.6 degrees with respect to the R-axis. The R-axis is typically angled with respect to the M-axis by approximately 32.4 degrees.

The planes and axes of the sapphire can be analyzed for example with X-ray or electron diffraction and can be determined about the actual sapphire single crystal.

In an embodiment, measurements of the sapphire crystal have revealed that A-plane is generally the strongest plane regarding to mechanical stress. However, the integration of sapphire to an optical element of a portable apparatus may be taken even further by controlling anisotropy (sometimes referred to as minor planes) such that the sapphire is orientated within the optical element of the apparatus for maximum strength and hence reliability.

In an embodiment, the crystal planes and directions in hexagonal systems may be indexed using Miller indices, wherein crystallographically equivalent planes have indices which appear dissimilar. To overcome this Miller-Bravais indexing system may be used, where a fourth index is introduced to the three of the Miller system.

A plane is then specified using four indices (hkil), where h, k, i and I are integers. The third index is always the negative of the sum of the first two and can be determined from the Miller system.

A direction is specified as [uvtw] where u, v, t and w are integers. The values of u, v and t are adjusted so that their sum is zero. The direction index cannot be written down from the equivalent Miller index.

When looking at FIG. 2 and using the Miller-Bravais indices for defining the planes, following mapping could be used:
C-plane 220 corresponds to {0 0 0 1} of the Miller-Bravais indices;
R-plane 240 corresponds to { 1̅ 0 1 2} of the Miller-Bravais indices;
A-plane 210 corresponds to {1 1 2̅ 0} of the Miller-Bravais indices; and
M-plane 230 corresponds to {1 0 1̅ 0} of the Miller-Bravais indices.

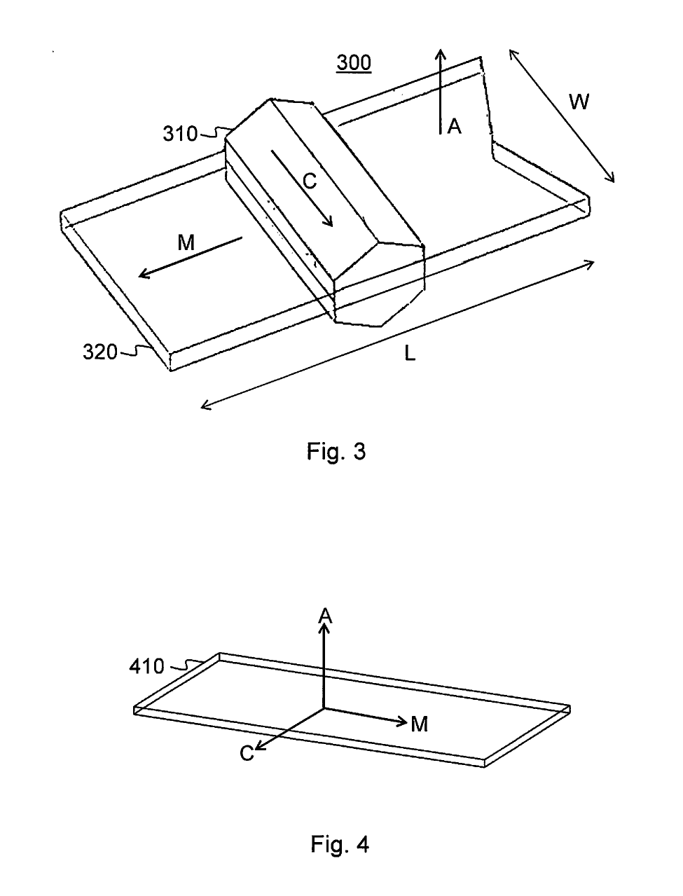

FIG. 3 presents a schematic view 300 of a sapphire crystallographic structure 310 for an optical element 320, in which various embodiments of the invention may be applied.

The optical element 320 may be a display glass, for example. The optical element 320 is developed by growing the sapphire crystallographic structure 310 in desired planes after detecting the planes and axes of the sapphire single crystal.

In an embodiment, the desired dimensions of the optical element 320 comprise a length L over a first axis and a width W over a second axis, as shown in FIG. 2. Orientation of the sapphire unit cell 310 is selected so that the plane of the optical element 320 corresponds to A-plane of the sapphire cell 310. The length L in this embodiment is greater than the width W, as can be seen from FIG. 3. The sapphire crystallographic structure is configured so that a main plane of the sapphire cell 310 is set to be parallel to the surface plane of the optical element 320 and two minor planes are set to be parallel to the first and second axes (W and L).

In an embodiment, the optical element 320 of an apparatus has a length L in a direction of a first axis and a width W in a direction of a second axis, wherein the length L is greater than or equal to the width W. The optical element 320 is developed and comprising a sapphire crystallographic structure 310 having a plurality of crystal planes with corresponding normal axes represented as C-axis, A-axis and M-axis, for example. A first crystal plane axis is configured to be perpendicular to the first axis L and the second axis W. A second crystal plane axis is configured to be parallel to the first axis L and a third crystal plane axis is configured to be parallel to the second axis W.

In an embodiment, a sapphire crystallographic structure has a plurality of crystal planes, wherein three major planes maybe be represented by three orthogonal axis, wherein a first crystal plane axis is configured to be perpendicular to the second crystal plane axis and the third crystal plane axis is configured to be perpendicular to the first crystal plane axis and the second crystal plane axis.

The plurality of crystal planes comprise at least:
A-plane with A-axis configured to be a normal axis of the A-plane;
C-plane with C-axis configured to be a normal axis of the C-plane, the C-axis being perpendicular to the A-axis; and
M-plane with M-axis configured to be a normal axis of the M-plane, the M-axis being perpendicular to the A-axis and the C-axis.

In an embodiment, the plurality of crystal planes comprises:
A-plane with A-axis configured to be a normal axis of the A-plane, the A-axis being perpendicular to the C-axis and perpendicular to the M-axis; and
C-plane with C-axis configured to be a normal axis of the C-plane, the C-axis being perpendicular to the A-axis and perpendicular to the M-axis; and
M-plane with M-axis configured to be a normal axis of the M-plane, the M-axis being perpendicular to the A-axis and perpendicular to the C-axis.

In an embodiment, the first crystal plane axis is the A-axis perpendicular to the W-axis and the L-axis, the second crystal plane axis is the M-axis parallel to the L-axis and the third crystal plane axis is the C-axis parallel to the W-axis.

Configuring the sapphire crystal 310 planes so that A-plane is parallel to the surface plane of the optical element 320, such as flat display screen, provides improved strength for the optical element 320. Even further strength for the optical element is achieved by aligning the M-axis of the M-plane parallel to a longer side L of the optical element 320 and the C-axis of the C-plane parallel to a shorter side of the optical element 320.

FIG. 4 presents a schematic view of an optical element 410, in which various embodiments of the invention may be applied. The optical element 410 is grown from a sapphire single cell configuring the crystal planes in such a way that A-axis is perpendicular to the optical element 410 surface, M-axis is parallel to a length axis of the optical element 410 and C-axis is parallel to a width axis of the optical element 410.

Such optical element 410 comprises A-plane sapphire and has different strengths in different directions. Because the thickness of the optical element may be desired to be as thin as possible the strength is very important.

With a fixed thickness of the optical element the strength may be measured. Some example measurements may indicate that for A-plane sapphire tested in the M-axis direction the sapphire element has strength of 1200 MPa, and if the A-plane sapphire is tested in the C-axis direction it has strength of 450 MPa. Such configuration provides good integration for mobile apparatus usage, for example. The stronger M-axis direction is aligned with the highest stressed direction in the mobile apparatus usage, the high stress direction in the mobile apparatus is usually the longer dimension but the high stress direction in the apparatus could equally be the shorter depending on the specific design. Measurement data presented is based on test work of certain sapphire, other sapphires may have different strengths depending on the way the sapphire is grown.

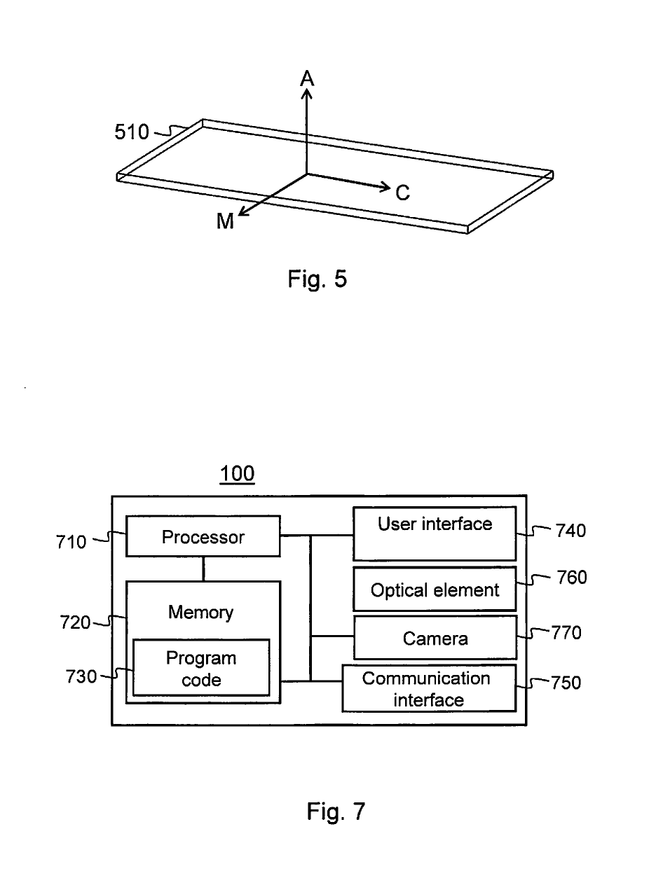

FIG. 5 presents another schematic view of an optical element 510, in which various embodiments of the invention may be applied. The optical element 510 is grown or cut from a sapphire single crystal configuring the crystal planes in such a way that A-axis is perpendicular to the optical element 510 surface, M-axis is parallel to a width axis of the optical element 510 and C-axis is parallel to a length axis of the optical element 510.

Such optical element 510 comprises A-plane sapphire and has different strengths in different directions compared to the optical element 410 of FIG. 4.

With a fixed thickness of the optical element 510 the strength may be measured and compared to the previous configuration 410. The measurements indicate that in the M-axis direction the sapphire element has strength of 1200 MPa, and if tested in the C-axis direction it has strength of 450 MPa. Such configuration provides poorer integration for mobile apparatus usage, compared to configuration 410 of FIG. 4. The weaker C-axis direction is aligned with the highest stressed direction in the mobile apparatus usage, the longer dimension. Measurement data presented is based on test work of certain sapphire, other sapphires may have different strengths depending on the way the sapphire is grown.

For A-plane sapphire the M-axis will always be considerably stronger than the C-axis but the absolute strength values may vary depending on the manufacturing route. The important issue is that for a given plane the different axes have different strengths and that these axes are aligned with a direction in the apparatus, depending on the design.

The integration shown in FIGS. 4-5 provides two different minor plane orientations for A-plane sapphire. Maximum strength of the sapphire and hence maximum product reliability is obtained when the high strength M-axis direction is aligned with long, high stress axis of the mobile apparatus. Whereas, if the sapphire crystal is aligned with the weaker direction C-axis direction parallel to the long and high stress axis of the mobile apparatus, then a weaker product with low reliability would be provided.

FIGS. 4-5 show only embodiments for A-plane sapphire but similar selections may be made also for other sapphire planes, such as M-plane, C-plane, and R-plane, correspondingly.

Both plane and orientation of a sapphire may be controlled for an optical element of a mobile apparatus, such as mobile phone or a tablet. By determining the different sapphire crystal planes, controlling and designing with desired anisotropy in the sapphire it is possible to maximize the use in mobile apparatuses.

In an embodiment, by understanding this surprising effect and configuring the optical element of sapphire in this way, a plurality of effects will be provided. Such advantageous effects comprise, but are not limited to allow optical elements and mobile apparatuses to be thinner, lighter and more reliable. Furthermore, sapphire material needed to manufacture the optical element is decreased and thus lowering the material costs for manufacturing the optical element.

In an embodiment, a higher stress direction of the apparatus is determined, for which apparatus an optical element comprising sapphire is to be implemented. Depending on the design and planned usage of the apparatus a certain direction may have higher stress than others. Furthermore, a higher strength axis of a sapphire for the optical element is determined. Based on the determinations the higher strength axis of the sapphire is aligned with the higher stress direction of the apparatus.

In an embodiment, a first sapphire crystal plane is selected to be parallel with a first plane of the optical element based on desired properties for the optical element. The desired properties may be optical properties, temperature properties, hardiness properties, manufacturing properties or like. After selecting the first sapphire crystal plane to be parallel with the first plane of the optical element, a higher stress direction of the apparatus is determined. Furthermore, a higher strength axis of a sapphire is determined for the optical element from the available sapphire axes and the higher strength axis aligned with the higher stress direction.

The higher strength axis is at least one of the following sapphire crystal axes:
A-axis;
C-axis;
M-axis;
R-axis; and
N-axis.

In an embodiment, a higher strength axis of a sapphire element is aligned with a higher stress direction of a portable apparatus.

In different embodiments, a sapphire crystal plane is selected to be parallel with a plane of an optical element based on desired properties for the optical element. Such parallel direction means substantially parallel in different embodiments. In certain embodiments the exactly parallel selections may be difficult to manufacture and the effects of the embodiments will be achieved as well if the directions slightly differ but still being substantially parallel. Furthermore, in some embodiments the slight difference but substantially parallel selections may provide further advantages. Parallel selection should thus be interpreted as substantially parallel selection. Same applies for perpendicular that should be interpreted as substantially perpendicular.

The desired properties may be optical properties, temperature properties, hardiness properties, manufacturing properties or like. After selecting the first sapphire crystal plane to be parallel with the first plane of the optical element, a higher stress direction of the apparatus is determined.

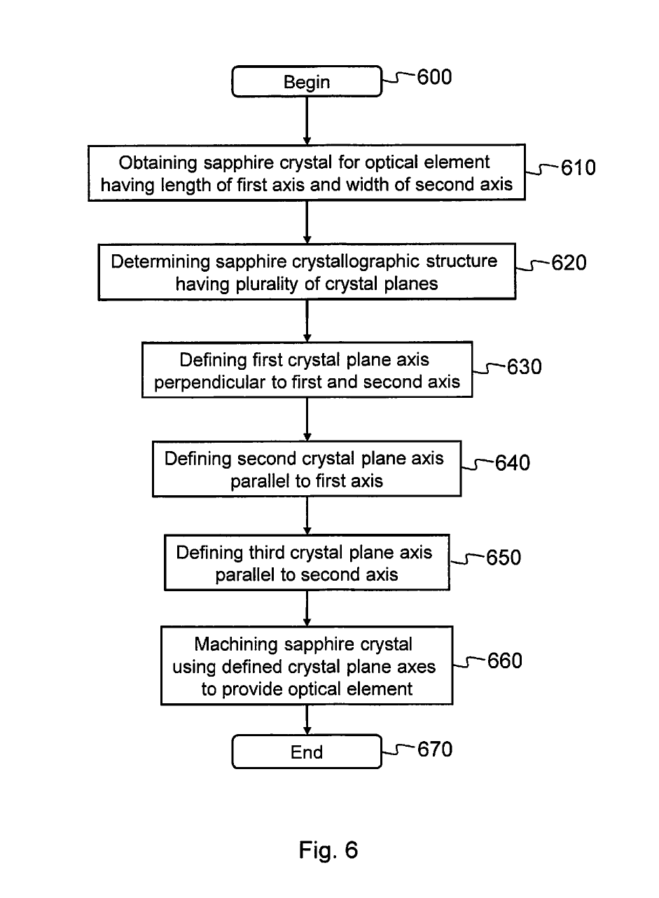

FIG. 6 shows operations in an apparatus in accordance with an example embodiment of the invention.

In step 600, a method for providing an optical element is started. In step 610, a sapphire crystal of sufficient size is obtained for the optical element, the optical element having a length in a direction of a first axis and a width in a direction of a second axis, wherein the length is greater than or equal to the width. In step 620, a sapphire crystallographic structure having a plurality of crystal planes is determined. In step 630, a first crystal plane axis is defined to be perpendicular to the first and the second axis. In step 640, a second crystal plane axis is defined to be parallel to the first axis. In step 650, a third crystal plane axis is defined to be parallel to the second axis. In step 660, the sapphire crystal is machined using the defined crystal plane axes to provide the optical element. In step 670, the method ends.

FIG. 7 presents an example block diagram of an apparatus 100 in which various embodiments of the invention may be applied. The apparatus 100 may be a user equipment (UE), user device or apparatus, such as a mobile terminal, a smart phone, a personal digital assistant (PDA), a laptop, a tablet or other communication device.

The general structure of the apparatus 100 comprises a user interface 740, a communication interface 750, a processor 710, a camera 770, and a memory 720 coupled to the processor 710. The apparatus 100 further comprises software 730 stored in the memory 720 and operable to be loaded into and executed in the processor 710. The software 730 may comprise one or more software modules and can be in the form of a computer program product. The apparatus 100 further comprises an optical element 760 comprising sapphire crystal unit cell with a plurality of crystal planes configured in a desired way to improve the strength of the optical element 760. The optical element 760 may also be integrated to another element of the apparatus 100, for example to the user interface 740.

The processor 710 may be, e.g. a central processing unit (CPU), a microprocessor, a digital signal processor (DSP), a graphics processing unit, or the like. FIG. 7 shows one processor 710, but the apparatus 100 may comprise a plurality of processors.

The memory 720 may be for example a non-volatile or a volatile memory, such as a read-only memory (ROM), a programmable read-only memory (PROM), erasable programmable read-only memory (EPROM), a random-access memory (RAM), a flash memory, a data disk, an optical storage, a magnetic storage, a smart card, or the like. The apparatus 100 may comprise a plurality of memories. The memory 720 may be constructed as a part of the apparatus 100 or it may be inserted into a slot, port, or the like of the apparatus 100 by a user. The memory 720 may serve the sole purpose of storing data, or it may be constructed as a part of an apparatus serving other purposes, such as processing data.

The user interface 740 may comprise circuitry for receiving input from a user of the apparatus 100, e.g., via a keyboard, graphical user interface shown on the display of the user apparatus 100, speech recognition circuitry, or an accessory device, such as a headset, and for providing output to the user via, e.g., a graphical user interface or a loudspeaker. The display of the user interface 740 may comprise a touch-sensitive display. The optical element 760 may be integrated to the user interface 740, such as a display, a keyboard, or a touchpad. The optical element may also be integrated to a cover part of the apparatus 100.

The optical element 760 may also be comprised by the camera 770, for providing a protective sheet for the camera optics. The optical element 760 may also provide a protective sheet for multiple elements of the apparatus 100. In an example embodiment, an optical element 760 is configured to provide a protective sheet for the display of the apparatus 100. The optical element may even cover most of even the whole front surface of the apparatus 100.

The communication interface module 750 implements at least part of radio transmission. The communication interface module 750 may comprise, e.g., a wireless interface module. The wireless interface may comprise such as near field communication (NFC), a WLAN, Bluetooth, infrared (IR), radio frequency identification (RF ID), GSM/GPRS, CDMA, WCDMA, or LTE (Long Term Evolution) radio module. The communication interface module 750 may be integrated into the user apparatus 100, or into an adapter, card or the like that may be inserted into a suitable slot or port of the apparatus 100. The communication interface module 750 may support one radio interface technology or a plurality of technologies. The apparatus 100 may comprise a plurality of communication interface modules 750.

A skilled person appreciates that in addition to the elements shown in FIG. 7, the apparatus 100 may comprise other elements, such as microphones, displays, as well as additional circuitry such as input/output (I/O) circuitry, memory chips, application-specific integrated circuits (ASIC), processing circuitry for specific purposes such as source coding/decoding circuitry, channel coding/decoding circuitry, ciphering/deciphering circuitry, and the like. Additionally, the apparatus 100 may comprise a disposable or rechargeable battery (not shown) for powering when external power if external power supply is not available.

Various embodiments have been presented. It should be appreciated that in this document, words comprise, include and contain are each used as open-ended expressions with no intended exclusivity.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means or in different combinations of embodiments without deviating from the characteristics of the invention.

Furthermore, some of the features of the above-disclosed embodiments of this invention may be used to advantage without the corresponding use of other features. As such, the foregoing description shall be considered as merely illustrative of the principles of the present invention, and not in limitation thereof. Hence, the scope of the invention is only restricted by the appended patent claims.

1. An optical element, the element having a length in a direction of a first axis and a width in a direction of a second axis, wherein the length is greater than or equal to the width, the optical element further comprising:
a sapphire crystallographic structure having a plurality of crystal planes, wherein a first crystal plane axis is configured to be perpendicular to the first and the second axis, a second crystal plane axis is configured to be parallel to the first axis and a third crystal plane axis is configured to be parallel to the second axis.

2. The optical element of claim 1, wherein the plurality of crystal planes comprising:
A-plane with A-axis configured to be a normal axis of the A-plane;
C-plane with C-axis configured to be a normal axis of the C-plane, the C-axis being perpendicular to the A-axis; and
M-plane with M-axis configured to be a normal axis of the M-plane, the M-axis being perpendicular to the A-axis and the C-axis.

3. The optical element of claim 2, wherein the first crystal plane axis is the A-axis, the second crystal plane axis is the M-axis and the third crystal plane axis is the C-axis.

4. The optical element of claim 1, wherein a fourth crystal plane axis is configured to be perpendicular to the first crystal plane axis and inclined to the second and the third crystal plane axes.

5. The optical element of claim 4, wherein the plurality of crystal planes comprising:
R-plane with R-axis configured to be a normal axis of the R-plane.

6. The optical element of claim 1, wherein the optical element comprising at least one of the following:
a display glass of an apparatus; and
a cover part of an apparatus.

7. The optical element of claim 1, wherein the element having a length in a direction of the M-axis and a width in a direction of the C-axis, wherein the length is greater than or equal to the width.

8. The optical element of claim 1, wherein the optical element is transparent.

9. A method for providing an optical element, the method comprising:
obtaining a sapphire crystal of sufficient size for the optical element, the optical element having a length in a direction of a first axis and a width in a direction of a second axis, wherein the length is greater than or equal to the width;
determining a sapphire crystallographic structure having a plurality of crystal planes;
defining a first crystal plane axis to be perpendicular to the first and the second axis, a second crystal plane axis to be parallel to the first axis and a third crystal plane axis to be parallel to the second axis; and
machining the sapphire crystal using the defined crystal plane axes to provide the optical element.

10. The method of claim 9, further comprising
defining the plurality of crystal planes as A-plane with A-axis configured to be a normal axis of the A-plane; C-plane with C-axis configured to be a normal axis of the C-plane, the C-axis being perpendicular to the A-axis; and M-plane with M-axis configured to be a normal axis of the M-plane, the M-axis being perpendicular to the A-axis and the C-axis.

11. The method of claim 10, wherein the first crystal plane axis is the A-axis, the second crystal plane axis is the M-axis and the third crystal plane axis is the C-axis.

12. The method of claim 11, further comprising:
machining the sapphire crystal using the defined crystal based axes to provide the optical element, wherein the element having a length in a direction of the M-axis and a width in a direction of the C-axis, wherein the length is greater than or equal to the width.

13. The method of claim 9, further comprising:
determining a higher stress direction of an apparatus;
determining a higher strength axis of a sapphire for the optical element; and
aligning the higher strength axis of the sapphire with the higher stress direction of the apparatus.

14. The method of claim 9, further comprising:
selecting a first sapphire crystal plane to be parallel with a first plane of the optical element based on desired properties for the optical element;
determining a higher stress direction of an apparatus;
determining a higher strength axis of a sapphire for the optical element; and
aligning the higher strength axis of the sapphire with the higher stress direction of the apparatus.

15. The method of claim 14, wherein the higher strength axis is at least one of the following sapphire crystal axis:
A-axis;
C-axis;
M-axis; and
R-axis.

16. An apparatus comprising an optical element of claim 1.

17. The apparatus of claim 16, wherein a higher strength axis of a sapphire element is aligned with a higher stress direction of the apparatus.

18. The apparatus of claim 16, wherein the apparatus being a portable apparatus comprising a cover part comprising the optical element.

19. The apparatus of claim 16, wherein the apparatus being a portable apparatus comprising a display comprising the optical element.

20. The apparatus of claim 19, wherein the optical element of the display comprises a transparent protection layer to provide a scratch-resistant surface for the display and enabling visibility for the display from different viewing angles.
